(19) United States
(12) Patent Application Publication
(10) Pub. No.: US 2026/0064002 A1
(43) Pub. Date: Mar. 5, 2026

(54) PHOTOSENSITIVE COMPOSITION AND FILM PREPARED FROM THE SAME

(71) Applicant: INDUSTRIAL TECHNOLOGY RESEARCH INSTITUTE, Hsinchu (TW)

(72) Inventors: Jyh-Long JENG, New Taipei City (TW); Jeng-Yu TSAI, Chiayi City (TW)

(73) Assignee: INDUSTRIAL TECHNOLOGY RESEARCH INSTITUTE, Hsinchu (TW)

(21) Appl. No.: 18/999,957

(22) Filed: Dec. 23, 2024

(30) Foreign Application Priority Data
Aug. 29, 2024 (TW) 113132617

(51) Int. Cl. G03F 7/075; G03F 7/038

(52) U.S. Cl. CPC G03F 7/0757; G03F 7/038

(57) ABSTRACT

A photosensitive composition and film prepared from the same are provided. The photosensitive composition includes 100 parts by weight of a cycloaliphatic epoxy resin, 2.5-20 parts by weight of a polyhedral oligomeric silsesquioxane with epoxy groups and 1.5-10 parts by weight of an oxetane compound, wherein the weight of the polyhedral oligomeric silsesquioxane with epoxy groups is greater than or equal to the weight of the oxetane compound.

### CROSS REFERENCE TO RELATED APPLICATIONS

This application claims priority of Taiwan Patent Application No. 113132617, filed on Aug. 29, 2024, the entirety of which is incorporated by reference herein.

### TECHNICAL FIELD

The disclosure relates to a photosensitive composition and a film prepared from the same.

### BACKGROUND

Photosensitive resin compositions are currently widely used in various semiconductor and microfabrication applications. In these applications, exposing the photosensitive resin composition on a substrate and processing the photosensitive resin composition with an appropriate developer can selectively remove the exposed or unexposed portions, forming a photoresist pattern.

With the increasing speed of electronic devices and the yearly advancements in high-density circuit board materials, the demand for finer processing is constantly rising. Therefore, photosensitive resin compositions must possess better photosensitivity, transparency, thermal tolerance, and chemical resistance. Many photosensitive resin compositions experience a reduction in photosensitivity, poor light transmittance, or an inability to form rollable dry films as the film thickness increases.

Accordingly, there is an urgent need to propose a novel photosensitive composition to solve the issues encountered with conventional technologies.

### SUMMARY

According to embodiments of the disclosure, the disclosure provides a photosensitive composition. The photosensitive composition includes 100 parts by weight of cycloaliphatic epoxy resin, 2.5 to 20 parts by weight of polyhedral oligomeric silsesquioxane (POSS) with epoxy groups, and 1.5 to 10 parts by weight of oxetane compound. The cycloaliphatic epoxy resin may have a structure represented by Formula (I)

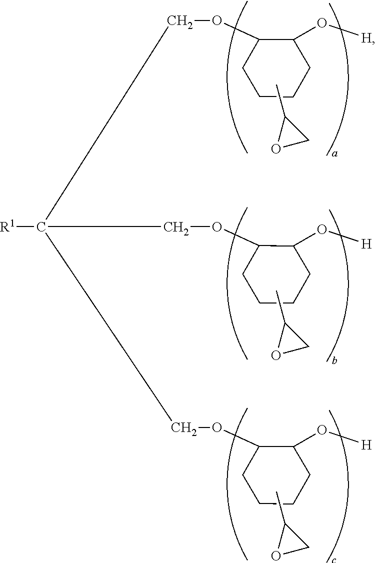

wherein R¹ is C1-C6 alkyl group; 13≥a≥1; 13≥b≥1; 13≥c≥1; and 20≥a+b+c≥3. The polyhedral oligomeric silsesquioxane with epoxy groups having a structure represented by Formula (II)

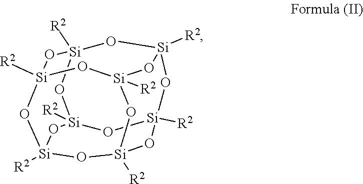

wherein R² are independently

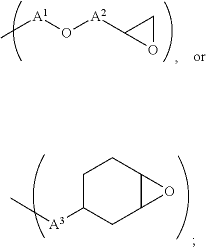

and A¹, A², and A³ are independently C1-C3 alkylene group. The weight of polyhedral oligomeric silsesquioxane with epoxy groups is greater than or equal to the weight of oxetane compound.

According to embodiments of the disclosure, the disclosure provides a film. The film is a cured product of the photosensitive composition of the disclosure.

A detailed description is given in the following embodiments.

### DETAILED DESCRIPTION

The photosensitive composition and film of the disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. As used herein, the term “about” in quantitative terms refers to plus or minus an amount that is general and reasonable to persons skilled in the art.

The disclosure provides a photosensitive composition that can be used to form a patterned film with excellent sidewall shape and high resolution. The film formed using the photosensitive composition of the disclosure may be applied as an insulating layer in electronic devices, such as microelectromechanical systems (MEMS), microreactors, capacitors, sensors, semiconductor devices, displays, bio-optoelectronic devices, and printed circuit boards. The photosensitive composition of the disclosure includes cycloaliphatic epoxy resin with a structure represented by Formula (I) (as described below), polyhedral oligomeric silsesquioxane with epoxy groups with a structure represented by Formula (II) (as described below), and oxetane compound. In some embodiments, the film prepared from the photosensitive composition of the disclosure maintains good light transmittance, adhesion, thermal tolerance, and chemical resistance even when thickened, and is suitable for forming a rollable dry film in a roll-to-roll process (the thick film is windable). Additionally, the photosensitive composition of the disclosure can be further combined with an aromatic epoxy resin (such as bisphenol A novolac epoxy resin) to achieve thick film rolling without cracking, while also maintaining high light transmittance.

According to embodiments of the disclosure, the photosensitive composition of the disclosure (such as negative photoresist composition) may include 100 parts by weight of cycloaliphatic epoxy resin, 2.5 to 20 parts by weight (such as 3, 4, 5, 6, 7, 8, 9, 10, 11, 12, 13, 14, 15, 16, 17, 18, or 19) of polyhedral oligomeric silsesquioxane (POSS) with epoxy groups, and 1.5 to 10 parts by weight (such as 2, 3, 4, 5, 6, 7, 8, or 9) of oxetane compound. The cycloaliphatic epoxy resin may have a structure represented by Formula (I)

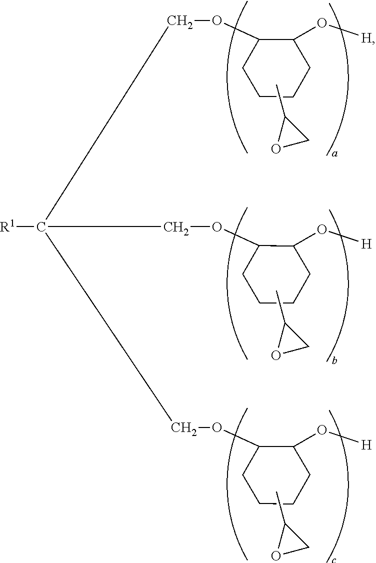

wherein R¹ is C1-C6 alkyl group; 13≥a≥1 (such as a may be 1, 2, 3, 4, 5, 6, 7, 8, 9, 10, 11, 12, or 13); 13≥b≥1 (such as b may be 1, 2, 3, 4, 5, 6, 7, 8, 9, 10, 11, 12, or 13); 13≥c≥1 (such as c may be 1, 2, 3, 4, 5, 6, 7, 8, 9, 10, 11, 12, or 13); and 20≥a+b+c≥3. The polyhedral oligomeric silsesquioxane with epoxy groups may have a structure represented by Formula (II)

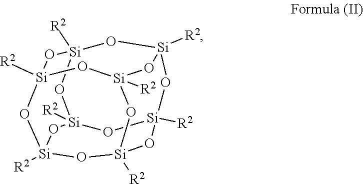

wherein R² is independently

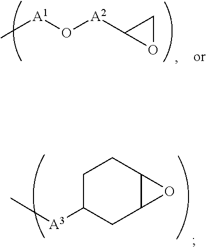

and A1, A2, and A3 may be independently C1-C3 alkylene group. According to embodiments of the disclosure, the weight of polyhedral oligomeric silsesquioxane with epoxy groups is greater than or equal to the weight of oxetane compound.

According to embodiments of the disclosure, when the additive amounts of polyhedral oligomeric silsesquioxane with epoxy groups and the oxetane compound are not within the specified ranges, and/or when the amount of polyhedral oligomeric silsesquioxane with epoxy groups is less than that of the oxetane compound, the film prepared using the photosensitive composition would not simultaneously exhibit high light transmittance, adhesion, thermal tolerance, and chemical resistance. Furthermore, the film would not be suitable for forming a rollable dry film in a roll-to-roll process.

According to embodiments of the disclosure, the C1-C6 alkyl group of the disclosure may be a linear or branched alkyl group. For example, the C1-C6 alkyl group may be methyl, ethyl, n-propyl, isopropyl, n-butyl, sec-butyl, iso-butyl, tert-butyl, pentyl, or hexyl. Therefore, R¹ may be methyl, ethyl, n-propyl, isopropyl, n-butyl, sec-butyl, iso-butyl, tert-butyl, pentyl, or hexyl.

According to embodiments of the disclosure, the C1-3 alkylene group of the disclosure may be a linear or branched alkylene group. For example, the C1-3 alkylene group may be methylene group, ethylene group, propylene group, or isopropylene group. Therefore, A1, A2, and A3 may be independently methylene group, ethylene group, propylene group, or isopropylene group.

According to embodiments of the disclosure, the oxetane compound of the disclosure may refer to a compound containing an oxetanyl group.

According to embodiments of the disclosure, the oxetane compound of the disclosure may be (3-ethyloxetan-3-yl)methyl methacrylate (OXMA), 4,4′-bis[(3-ethyl-3-oxetanyl)methoxymethyl]biphenyl (OXBP), 1,4-bis[(3-ethyl-3-oxetanylmethoxy)methyl]benzene (OXT-121), 3-ethyl-3 [(2-ethylhexyloxy)methyl]oxetane (OXT-212), 3-ethyl-3-(phenoxymethyl)oxetane (OXT-211), 3-ethyl-3-hydroxymethyloxetane, 3,3′-(oxybis(methylene))bis(3-ethyloxetane), bis((3-ethyloxetan-3-yl)methyl)isophthalate (OXIPA), or a combination thereof.

According to embodiments of the disclosure, the photosensitive composition of the disclosure may further include 2.5 to 14 parts by weight (such as 3, 4, 5, 6, 7, 8, 9, 10, 11, 12, or 13) of polycaprolactone polyol.

According to embodiments of the disclosure, the weight of polyhedral oligomeric silsesquioxane with epoxy groups is greater than or equal to the weight of the polycaprolactone polyol.

According to embodiments of the disclosure, the polycaprolactone polyol may have at least two groups having a structure represented by Formula (III) (such as polycaprolactone dihydric alcohol or polycaprolactone trihydric alcohol)

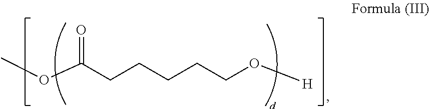

wherein d is 1 to 10.

According to embodiments of the disclosure, the weight average molecular weight of polycaprolactone polyol may be 300 to 1,500 g/mol (such as 500, 600, 700, 800, 900, 1,000, 1,100, 1,200, 1,300, or 1,400 g/mol).

According to embodiments of the disclosure, when the additive amounts of polyhedral oligomeric silsesquioxane with epoxy groups, oxetane compound, and polycaprolactone polyol are not within the aforementioned ranges, and/or when the amount of polyhedral oligomeric silsesquioxane with epoxy groups is less than that of the oxetane compound, and/or when the amount of polyhedral oligomeric silsesquioxane with epoxy groups is less than that of the polycaprolactone polyol, the film prepared from the photosensitive composition cannot simultaneously exhibit high light transmittance, adhesion, thermal tolerance, and chemical resistance. Furthermore, the film is not suitable for forming a rollable dry film using a roll-to-roll processing method.

According to embodiments of the disclosure, the photosensitive composition of the disclosure may further include 2.5 to 20 parts by weight (such as 3, 4, 5, 6, 7, 8, 9, 10, 11, 12, 13, 14, 15, 16, 17, 18, or 19 parts by weight) of photoacid generator.

According to embodiments of the disclosure, the photoacid generator of the disclosure may be onium salt, triarylsulfonium salts, alkylarylsulfonium salt, diaryliodonium salts, diarylchloronium salts, diarylbromonium salts, sulfonates salt, diazonium salt, diazonaphthoquinone sulfonate, or a combination thereof.

According to embodiments of the disclosure, the photosensitive composition of the disclosure may further include a solvent, resulting in that the cycloaliphatic epoxy resin having a structure represented by Formula (I), the polyhedral oligomeric silsesquioxane with epoxy groups having a structure represented by Formula (II), the oxetane compound, the polycaprolactone polyol, and the photoacid generator are dispersed in the solvent. According to embodiments of the disclosure, the solid content of the photosensitive composition is not limited and can be optionally modified by a person of ordinary skill in the field, According to embodiments of the disclosure, the solid content of the composition may be about 10 wt % to 90 wt % (such as about 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, or 85 wt %). Herein, the solid content refers to the weight percentage of all components in the photosensitive composition except for the solvent, based on the total weight of the photosensitive composition.

According to embodiments of the disclosure, the solvent is not specifically limited and may include benzene, toluene, xylene, ethylbenzene, diethylbenzene, trimethylbenzene, triethylbenzene, cyclohexane, decahydronaphthalene, dipentene, pentane, hexane, heptane, octane, nonane, decane, ethyl cyclohexane, methyl cyclohexane, cyclohexene, p-menthane, dipropyl ether, dibutyl ether, anisole, butyl acetate, pentyl acetate, methyl isobutyl ketone, cyclohexylbenzene, cyclohexanone, cyclopentanone (CPN), triglyme, 1,3-dimethyl-2-imidazolidinone (DMI), N-methyl-2-pyrrolidone (NMP), methyl ethyl ketone (MEK), N,N-dimethylacetamide (DMAc), γ-butyrolactone (GBL), N,N-dimethylformamide (DMF), propylene glycol methyl ether acetate (PGMEA), dimethyl sulfoxide (DMSO), or combinations thereof.

In some embodiments, the photosensitive composition of the disclosure may consist of the cycloaliphatic epoxy resin having a structure represented by Formula (I), the polyhedral oligomeric silsesquioxane with epoxy groups having a structure represented by Formula (II), the oxetane compound, the polycaprolactone polyol, and the photoacid generator.

Namely, the cycloaliphatic epoxy resin having a structure represented by Formula (I), the polyhedral oligomeric silsesquioxane with epoxy groups having a structure represented by Formula (II), the oxetane compound, the polycaprolactone polyol, and the photoacid generator may serve as the main ingredients of the photosensitive composition of the disclosure.

According to embodiments of the disclosure, the photosensitive composition may optionally include a minor ingredient. According to embodiments of the disclosure, in the photosensitive composition, the content of the main ingredient may be 90 wt % to 100 wt % (such as 90 wt %, 92 wt %, 94 wt %, 96 wt %, or 98 wt %), based on the total weight of the photosensitive composition. According to embodiments of the disclosure, the minor ingredient may be an additive (such as an adhesion modifier, leveling agent, surface treatment agent, viscosity modifier, stabilizer, or antioxidant). According to embodiments of the disclosure, the photosensitive composition may substantially consist of the solvent, the cycloaliphatic epoxy resin having a structure represented by Formula (I), the polyhedral oligomeric silsesquioxane with epoxy groups having a structure represented by Formula (II), the oxetane compound, the polycaprolactone polyol, and the photoacid generator.

According to embodiments of the disclosure, when the additive amounts of the polyhedral oligomeric silsesquioxane with epoxy groups, the oxetane compound, the polycaprolactone polyol, and the photoacid generator are not within the aforementioned ranges, the obtained film using the photosensitive composition cannot simultaneously achieve high light transmittance, good adhesion, thermal tolerance, and chemical resistance. Furthermore, the film is not suitable for forming a roll-type dry film through a roll-up process.

According to embodiments of the disclosure, the photosensitive composition may further include 0.1 to 100 parts by weight (such as 0.5, 1, 2, 5, 10, 15, 20, 25, 30, 35, 40, 45, 50, 55, 60, 65, 70, 75, 80, 85, 90, 95, or 98) of aromatic epoxy resin (such as bisphenol A novolac epoxy resin). According to embodiments of the disclosure, when the amount of bisphenol A novolac epoxy resin is too high, the light transmittance of the obtained film using the photosensitive composition will decrease. Moreover, it is unsuitable for forming a roll-type dry film through a roll-up process.

According to embodiments of the disclosure, the bisphenol A novolac epoxy resin may have a structure represented by Formula (IV)

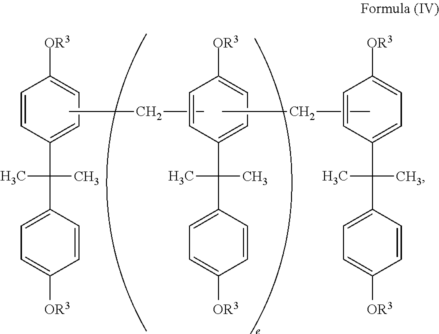

wherein R³ is independently hydrogen or glycidyl group, and at least two R³ are glycidyl groups (such as 2, 3, 4, 5, 6, 7, 8, 9, or 10 of R³ are glycidyl groups); and e represents an average number of repeating units, and e may be within a range of 1 and 30 (such as 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30).

According to embodiments of the disclosure, the disclosure also provides a film (such as negative dry film photoresist), wherein the film is a cured product of the photosensitive composition of the disclosure. According to embodiments of the disclosure, the film of the disclosure is a dry film obtained from the photosensitive composition of the disclosure after undergoing a coating process and subsequent drying.

According to embodiments of the disclosure, the method for preparing the film and its usage may include the following steps. First, the photosensitive composition is coated onto a carrier film and dried to obtain the film. According to embodiments of the disclosure, the film can be bonded to a substrate using a transfer printing process, followed by exposure and development processes.

The method for coating the photosensitive composition is not limited and may include screen printing, spin coating, bar coating, blade coating, roller coating, dip coating, spray coating, or brush coating.

According to embodiments of the disclosure, the carrier film may be polyethylene terephthalate (PET) film.

According to embodiments of the disclosure, the light source for the exposure process may be ultraviolet (UV) light, with a wavelength ranging from 150 nm to 400 nm, and the exposure dose may be from 50 mJ/cm² to 200 mJ/cm² (such as 70 mJ/cm², 100 mJ/cm², 120 mJ/cm², 150 mJ/cm², or 180 mJ/cm²).

According to embodiments of the disclosure, the developer may be an aqueous solution of alkali metal salts, such as sodium carbonate aqueous solution or potassium carbonate aqueous solution. According to embodiments of the disclosure, the concentration of the alkali metal salt in the aqueous solution may be from 0.1 wt % to 5 wt %, based on the total weight of the aqueous solution of alkali metal salt.

Below, exemplary embodiments will be described in detail so as to be easily realized by a person having ordinary knowledge in the art. The inventive concept may be embodied in various forms without being limited to the exemplary embodiments set forth herein.

### Photosensitive Composition and Film

### Example 1

100 parts by weight of trifunctional aliphatic epoxy resin (with a trade number of EHPE3150, commercially available from DAICEL) was dissolved in 33.3 parts by weight of cyclohexanone. The result was heated to 80° C. and then stirred sufficiently, obtaining a solution. After cooling the solution to room temperature, 2.5 parts by weight of polyhedral oligomeric silsesquioxane modified with glycidyl groups (having a molecular weight of 1337.88, commercially available from Toyotsu Chemiplas Corporation with a trade number of EP0409), 1.5 parts by weight of 4,4′-bis[(3-ethyl-3-oxetanyl)methoxymethyl]biphenyl (commercially available from Ube Industries, Ltd. with a trade number of ETERNACOLL OXBP), 2.5 parts by weight of polycaprolactone polyol (having a molecular weight of 550 g/mole, commercially available from Dow Chemical with a trade number of Tone 305), and 2.5 parts by weight of triarylsulfonium salt (with a trade number of CPI101A, commercially available from San-Apro Ltd.) (serving as photoacid generator) were added into the solution. After sufficient stirring, a photosensitive composition was obtained.

Next, the photosensitive composition was coated on a polyethylene terephthalate (PET) release film (with a thickness of 188 μm, commercially available from TOYOBO Co., LTD.) via a blade coating, obtaining a coating. Next, the coating was baked at 85° C. for 90 minutes to remove the solvent, obtaining Photosensitive film (1) (with a thickness of about 220 μm).

### Example 2

Example 2 was performed in the same manner as in Example 1, but the amounts of polyhedral oligomeric silsesquioxane modified with glycidyl groups (EP0409), 4,4′-bis[(3-ethyl-3-oxetanyl)methoxymethyl]biphenyl (ETERNACOLL OXBP), polycaprolactone polyol (Tone 305), and triarylsulfonium salt (CPI101A) were changed according to Table 1, resulting in Photosensitive film (2) (with a thickness of about 220 μm).

### Comparative Examples 1-4 and Example 3

Comparative Examples 1-4 and Example 3 were performed in the same manner as in Example 1, but the amounts of polyhedral oligomeric silsesquioxane modified with glycidyl groups (EP0409), 4,4′-bis[(3-ethyl-3-oxetanyl)methoxymethyl]biphenyl (ETERNACOLL OXBP), polycaprolactone polyol (Tone 305), and triarylsulfonium salt (CPI101A) were changed according to Table 1, resulting in Photosensitive films (3)-(7) (with a thickness of about 220 μm).

TABLE 1

| | EHPE3150 | EP0409 | ETERNACOLL | Tone 305 | CPI101A |
|---|---|---|---|---|---|
| | (parts by | (parts by | OXBP (parts by | (parts by | (parts by |
| | weight) | weight) | weight) | weight) | weight) |
| Example 1 | 100 | 2.5 | 1.5 | 2.5 | 2.5 |
| Example 2 | 100 | 10 | 6 | 5 | 10 |
| Comparative | 100 | 0 | 5 | 5 | 5 |
| Example 1 | | | | | |
| Comparative | 100 | 10 | 0 | 2.5 | 5 |
| Example 2 | | | | | |
| Comparative | 100 | 15 | 15 | 2.5 | 10 |
| Example 3 | | | | | |
| Comparative | 100 | 10 | 6 | 18 | 10 |
| Example 4 | | | | | |
| Example 3 | 100 | 2.5 | 2 | 4.5 | 3 |

Next, the light transmittance, adhesion, glass transition temperature (Tg), chemical resistance, and windability of the photosensitive films described in Examples 1-3 and Comparative Examples 1-4 were evaluated, and the results are shown in Table 2. The measurement of light transmittance of the films (@600 nm) was conducted using a UV/visible spectrophotometer. The evaluation of adhesion involved subjecting a 220 μm thick film to development; if there was no pattern delamination on the substrate, it was marked as O, while delamination occurred, it was marked as X. The glass transition temperature (Tg) of the films was determined using differential scanning calorimetry (DSC) with a heating rate of 10° C. per minute. For chemical resistance evaluation, the films were immersed in 1-methoxy-2-propanol acetate (PGMEA) heated to 70° C. for 3 minutes, then rinsed with water for 5 minutes. If there was no significant change in film thickness or shape after this treatment, it was marked as O; if there was a change, it was marked as X. The evaluation of windability involved rolling the film using a scroll device; if it could be rolled, it was marked as O, and if it could not, it was marked as X.

TABLE 2

| | | | glass | | |
|---|---|---|---|---|---|
| | light | | transition | | |
| | transmittance | | temperature | chemical | |
| | (%) | adhesion | (° C.) | resistance | windability |
| Photosensitive | 92.1 | ◯ | 173 | ◯ | ◯ |
| film | | | | | |
| (1)/Example 1 | | | | | |
| Photosensitive | 92.3 | ◯ | 171 | ◯ | ◯ |
| film | | | | | |
| (2)/Example 2 | | | | | |
| Photosensitive | 91.5 | X | 165 | X | ◯ |
| film (3)/ | | | | | |
| Comparative | | | | | |
| Example 1 | | | | | |
| Photosensitive | 91.8 | ◯ | 169 | X | ◯ |
| film (4)/ | | | | | |
| Comparative | | | | | |
| Example 2 | | | | | |
| Photosensitive | 91.3 | ◯ | 158 | X | ◯ |
| film (5)/ | | | | | |
| Comparative | | | | | |
| Example 3 | | | | | |
| Photosensitive | 92.1 | ◯ | 150 | X | ◯ |
| film (6)/ | | | | | |
| Comparative | | | | | |
| Example 4 | | | | | |
| Photosensitive | 91.2 | ◯ | 168 | ◯ | ◯ |
| film (7)/ | | | | | |
| Example 3 | | | | | |

As shown in Table 2, the films prepared from the photosensitive compositions of the disclosure (i.e., Photosensitive films (1), (2), and (7) described in Examples 1, 2 and 3) exhibit high light transmittance (greater than 90%), relatively high glass transition temperature (Tg) (greater than or equal to 168° C.), good adhesion, chemical resistance, and windability. When the photosensitive composition does not include polyhedral oligomeric silsesquioxane (POSS) with epoxy groups, the adhesion and chemical resistance of the film prepared from the photosensitive composition (i.e., Photosensitive film (3) described in Comparative Example 1) deteriorates. When the photosensitive composition does not include oxetane compounds, the chemical resistance of the film prepared from the photosensitive composition (i.e., Photosensitive film (4) described in Comparative Example 2) declines. When the amount of oxetane compound in the photosensitive composition is too high, the glass transition temperature of the film prepared from the photosensitive composition (i.e., Photosensitive film (5) described in Comparative Example 3) decreases, and the chemical resistance also worsens. Similarly, when the amount of polycaprolactone polyol in the photosensitive composition is too high, the glass transition temperature of the film prepared from the photosensitive composition (i.e., Photosensitive film (6) described in Comparative Example 4) decreases, and the chemical resistance also deteriorates.

### Example 4

100 parts by weight of trifunctional aliphatic epoxy resin (with a trade number of EHPE3150, commercially available from DAICEL) (a+b+c was about 15) was dissolved in 33.3 parts by weight of cyclopentanone (CPN). The result was heated to 80° C. and then stirred sufficiently, obtaining a solution. After cooling the solution to room temperature, 20 parts by weight of polyhedral oligomeric silsesquioxane modified with glycidyl groups (having a molecular weight of 1337.88, commercially available from Toyotsu Chemiplas Corporation with a trade number of EP0409), 10 parts by weight of 4,4′-bis[(3-ethyl-3-oxetanyl)methoxymethyl]biphenyl) (commercially available from Ube Industries, Ltd. with a trade number of ETERNACOLL OXBP), 14 parts by weight of polycaprolactone polyol (with a trade number of Tone 305, commercially available from Dow Chemical), 20 parts by weight of triarylsulfonium salt (with a trade number of CPI101A, commercially available from San-Apro Ltd.) (serving as photoacid generator), and 100 parts by weight of bisphenol A novolac epoxy resin (commercially available from Mitsubishi Chemicals Corp. with a trade number of 157S70) were added into the solution. After sufficient stirring, a photosensitive composition was obtained.

Next, the photosensitive composition was coated on a polyethylene terephthalate (PET) release film (with a thickness of 188 μm, commercially available from TOYOBO Co., LTD.) via a blade coating, obtaining a coating. Next, the coating was baked at 60° C. and 95° C., respectively for 30 minutes, to remove the solvent, obtaining Photosensitive film (8) (with a thickness of about 220 μm).

### Examples 5 and 6

Examples 5 and 6 were performed in the same manner as in Example 4, but the amounts of polyhedral oligomeric silsesquioxane modified with glycidyl groups (EP0409), 4,4′-bis[(3-ethyl-3-oxetanyl)methoxymethyl]biphenyl (ETERNACOLL OXBP), polycaprolactone polyol (Tone 305), triarylsulfonium salt (CPI101A), and bisphenol A novolac epoxy resin (157S70) were changed according to Table 3, resulting in Photosensitive films (9) and (10) (with a thickness of about 220 μm).

### Comparative Examples 5-8

Comparative Examples 5-8 were performed in the same manner as Example 4, but the amounts of the trifunctional cycloaliphatic epoxy resin (EHPE3150), polyhedral oligomeric silsesquioxane modified with glycidyl groups (EP0409), 4,4′-bis[(3-ethyl-3-oxetanyl)methoxymethyl]biphenyl (ETERNACOLL OXBP), polycaprolactone polyol (Tone 305), triarylsulfonium salt (CPI101A), and bisphenol A novolac epoxy resin (157S70) were modified according to Table 3, resulting in Photosensitive films (11)-(14) (with a thickness of about 220 μm).

TABLE 3

| | EHPE3150 | EP0409 | ETERNACOLL | Tone 305 | CPI101A | 157S70 |
|---|---|---|---|---|---|---|
| | (parts by | (parts by | OXBP(parts | (parts by | (parts by | (parts by |
| | weight) | weight) | by weight) | weight) | weight) | weight) |
| Example 4 | 100 | 20 | 10 | 14 | 20 | 100 |
| Example 5 | 100 | 20 | 10 | 10 | 10 | 100 |
| Example 6 | 100 | 11.43 | 7.14 | 11.43 | 11.43 | 42.86 |
| Comparative Example 5 | 100 | 8 | 10 | 10 | 10 | 100 |
| Comparative Example 6 | 100 | 22 | 6 | 10 | 10 | 100 |
| Comparative Example 7 | 0 | 0 | 0 | 5 | 5 | 200 |
| Comparative Example 8 | 100 | 12.5 | 12.5 | 12.5 | 20 | 150 |

Next, the light transmittance, adhesion, glass transition temperature (Tg), chemical resistance, and windability of the photosensitive films described in Examples 4-6 and Comparative Examples 5-8 were evaluated, and the results are shown in Table 4.

TABLE 4

| | | | glass | | |
|---|---|---|---|---|---|
| | light | | transition | | |
| | transmittance | | temperature | chemical | |
| | (%) | adhesion | (° C.) | resistance | windability |
| Photosensitive | 91.2 | ◯ | 176 | ◯ | ◯ |
| film | | | | | |
| (8)/Example 4 | | | | | |
| Photosensitive | 90.8 | ◯ | 175 | ◯ | ◯ |
| film | | | | | |
| (9)/Example 5 | | | | | |
| Photosensitive | 91.4 | ◯ | 174 | ◯ | ◯ |
| film | | | | | |
| (10)/Example | | | | | |
| 6 | | | | | |
| Photosensitive | 91 | X | 171 | X | ◯ |
| film (11)/ | | | | | |
| Comparative | | | | | |
| Example 5 | | | | | |
| Photosensitive | 90.8 | X | 175 | ◯ | X |
| film (12)/ | | | | | |
| Comparative | | | | | |
| Example 6 | | | | | |
| Photosensitive | 82.3 | ◯ | 184 | ◯ | ◯ |
| film (13)/ | | | | | |
| Comparative | | | | | |
| Example 7 | | | | | |
| Photosensitive | 88.2 | ◯ | 176 | ◯ | X |
| film (14)/ | | | | | |
| Comparative | | | | | |
| Example 8 | | | | | |

As shown in Table 4, the photosensitive composition of the disclosure can further incorporate bisphenol A novolac epoxy resin within a specific range of amounts, and the obtained films (i.e., Photosensitive films (8)-(10) described in Examples 4-6) still exhibit high light transmittance (greater than 90%). When the amount of polyhedral oligomeric silsesquioxane with epoxy groups in the photosensitive composition is less than that of the oxetane compound, and the amount of polyhedral oligomeric silsesquioxane with epoxy groups is less than that of the polycaprolactone polyol, the obtained film from the photosensitive composition (i.e., Photosensitive film (11) described in Comparative Example 5) shows poorer adhesion and chemical resistance. When the amount of polyhedral oligomeric silsesquioxane with epoxy groups in the photosensitive composition is too high, the obtained film (i.e., Photosensitive film (12) described in Comparative Example 6) demonstrates poorer adhesion and lacks windability. When the photosensitive composition merely includes polycaprolactone polyol, a photoacid generator, and bisphenol A novolac epoxy resin, the obtained film (i.e., Photosensitive film (13) described in Comparative Example 7) exhibits inferior light transmittance. When the additive amount of bisphenol A novolac epoxy resin in the photosensitive composition is too high, the obtained film (i.e., Photosensitive film (14) described in Comparative Example 8) shows poorer light transmittance and lacks windability.

Accordingly, due to its specific ingredients and content of the photosensitive composition of the disclosure, the film prepared from the photosensitive composition of the disclosure maintains good light transmittance, adhesion, thermal tolerance, and chemical resistance even when thickened, furthermore making it suitable for roll-to-roll processing to create dry films. Additionally, the photosensitive composition of the disclosure can also be further combined with bisphenol A novolac epoxy resin to achieve thick films that do not crack during rolling, while maintaining high light transmittance.

It will be clear that various modifications and variations can be made to the disclosed methods and materials. It is intended that the specification and examples be considered as exemplary only, with the true scope of the disclosure being indicated by the following claims and their equivalents.

What is claimed is:

1. A photosensitive composition, comprising:
100 parts by weight of cycloaliphatic epoxy resin, wherein the cycloaliphatic epoxy resin has a structure represented by Formula (I) 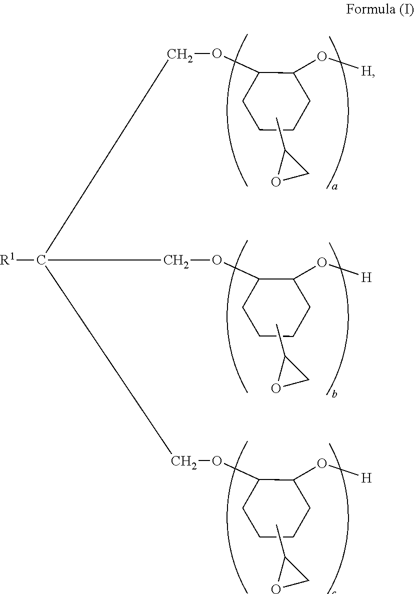
wherein R¹ is C1-C6 alkyl group; 13≥a≥1; 13≥b≥1; 13≥c≥1; and 20≥a+b+c≥3;
2.5 to 20 parts by weight of polyhedral oligomeric silsesquioxane with epoxy groups, wherein the polyhedral oligomeric silsesquioxane with epoxy groups has a structure represented by Formula (II) 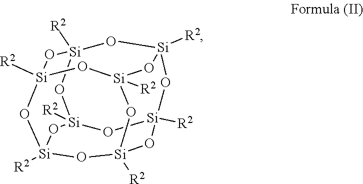
wherein R² is independently 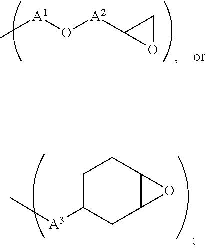
and A1, A2, and A3 are independently C1-C3 alkylene group;
1.5 to 10 parts by weight of oxetane compound, wherein a weight of the polyhedral oligomeric silsesquioxane with epoxy groups is greater than or equal to a weight of the oxetane compound;
2.5 to 14 parts by weight of polycaprolactone polyol; and
2.5 to 20 parts by weight of photoacid generator.

2. The photosensitive composition as claimed in claim 1, wherein the oxetane compound is (3-ethyloxetan-3-yl)methyl methacrylate, 4,4′-bis[(3-ethyl-3-oxetanyl)methoxymethyl]biphenyl, 1,4-bis[(3-ethyl-3-oxetanylmethoxy)methyl]benzene, 3-ethyl-3 [(2-ethylhexyloxy)methyl]oxetane, 3-ethyl-3-(phenoxymethyl)oxetane, 3-ethyl-3-hydroxymethyloxetane, 3,3′-(oxybis(methylene))bis(3-ethyloxetane), bis((3-ethyloxetan-3-yl)methyl)isophthalate, or a combination thereof.

3. The photosensitive composition as claimed in claim 1, wherein a weight of the polyhedral oligomeric silsesquioxane with epoxy groups is greater than or equal to a weight of the polycaprolactone polyol.

4. The photosensitive composition as claimed in claim 1, wherein the polycaprolactone polyol has at least two groups having a structure represented by Formula (III) 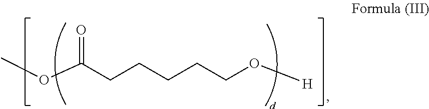
wherein d is 1 to 10.

5. The photosensitive composition as claimed in claim 1, wherein a weight average molecular weight of the polycaprolactone polyol is 300 g/mol to 1,500 g/mol.

6. The photosensitive composition as claimed in claim 1, wherein the photoacid generator is onium salt, triarylsulfonium salts, alkylarylsulfonium salt, diaryliodonium salts, diarylchloronium salts, diarylbromonium salts, sulfonates salt, diazonium salt, diazonaphthoquinone sulfonate, or a combination thereof.

7. The photosensitive composition as claimed in claim 1, further comprising:
0.1 to 100 parts by weight of aromatic epoxy resin.

8. The photosensitive composition as claimed in claim 7, wherein the aromatic epoxy resin is bisphenol A novolac epoxy resin having a structure represented by Formula (IV) 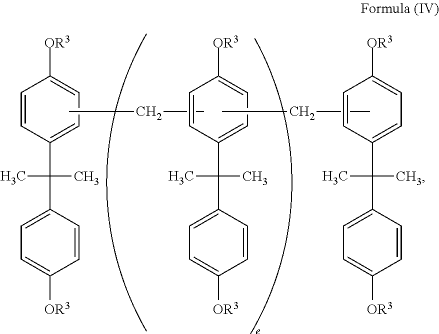
wherein R³ is independently hydrogen or glycidyl group, and at least two R³ are glycidyl groups; and e is 1 to 30.

9. A film, which is a cured product of the photosensitive composition as claimed in claim 1.
